(19) United States
(12) Patent Application Publication
(10) Pub. No.: US 2025/0311392 A1
(43) Pub. Date: Oct. 2, 2025

(54) CAPACITOR STRUCTURE

(71) Applicant: AP Memory Technology Corporation, Hsinchu County (TW)

(72) Inventors: Kuan-Ting Chen, HsinChu (TW); Yun-Jui Lee, HsinChu (TW); Chun-Yi Lin, HsinChu (TW); Chin-Hung Liu, HsinChu (TW)

(73) Assignee: AP Memory Technology Corporation, Hsinchu County (TW)

(21) Appl. No.: 18/616,203

(22) Filed: Mar. 26, 2024

(51) Int. Cl. H01L 27/08; H01L 23/498; H01L 23/528

(52) U.S. Cl. CPC H10D 84/212; H01L 23/49838; H01L 23/528

(57) ABSTRACT

A capacitor structure is provided. The capacitor structure includes a substrate, a plurality of capacitor cells, a first cell plate, a plurality of second cell plates, and a plurality of vias. The plurality of capacitor cells are formed upon the substrate. The first cell plate is disposed between the substrate and the plurality of capacitor cells, and the plurality of second cell plates are disposed on the plurality of capacitor cells respectively. The vias are disposed on the second cell plates. The plurality of capacitor cells are connected in series.

### BACKGROUND

### Technical Field

The present disclosure relates to a capacitor structure.

### Description of Related Art

Integrated circuits (IC) generally include a variety of passive components. Capacitors are among some of the more common passive components that are widely used in ICs for various applications.

In general silicon capacitor, since the connecting conductors to the capacitor have high resistance characteristics, the decrease of parasitic resistance characteristics of the silicon capacitor are required. To improve the parasitic resistance characteristics, the number of connecting conductors must be increased. However, the more the number of connecting conductors, the larger the device area, which is not conducive to area design.

### SUMMARY

According to an embodiment of the disclosure, a capacitor structure includes a substrate, a plurality of capacitor cells, a first cell plate, a plurality of second cell plates, and a plurality of vias. The plurality of capacitor cells are formed upon the substrate. The first cell plate is disposed between the substrate and the plurality of capacitor cells, and the plurality of second cell plates are disposed on the plurality of capacitor cells respectively. The plurality of vias are disposed on the plurality of second cell plates.

According to another embodiment of the disclosure, a capacitor structure includes at least one bottom cell plate, a plurality of top cell plates, a first via, and a second via. The capacitor cells are disposed on the at least one bottom cell plate. The top cell plates are disposed on the capacitor cells. The first via is disposed on one of the top cell plates, and the second via is disposed on another one of the top cell plates, wherein the capacitor cells are connected in series between the first via and the second via.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A illustrates a cross-sectional view of a capacitor structure according to some embodiments of the present disclosure.

FIG. 1B illustrates a top view of the capacitor structure of FIG. 1A.

FIG. 2 illustrates a cross-sectional view of a capacitor structure according to some embodiments of the present disclosure.

FIG. 3 illustrates a cross-sectional view of a capacitor structure according to some embodiments of the present disclosure.

FIG. 4A is a schematic cross-sectional view of a capacitor structure of an experimental example.

FIG. 4B is a schematic cross-sectional view of a capacitor structure of a comparative example.

FIG. 5 is a voltage curve graph along times of the experimental example and the comparative example.

FIG. 6 is an impedance curve graph of the experimental example and the comparative example.

### DESCRIPTION OF THE EMBODIMENTS

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct via, and may also include embodiments in which additional features may be formed between the first and second features, such that the first and second features may not be in direct via. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

As used herein, the terms such as “first” and “second” describe various elements, components, regions, layers and/or sections, these elements, components, regions, layers and/or sections should not be limited by these terms. These terms may be only used to distinguish one element, component, region, layer or section from another. The terms such as “first” and “second” when used herein do not imply a sequence or order unless clearly indicated by the context.

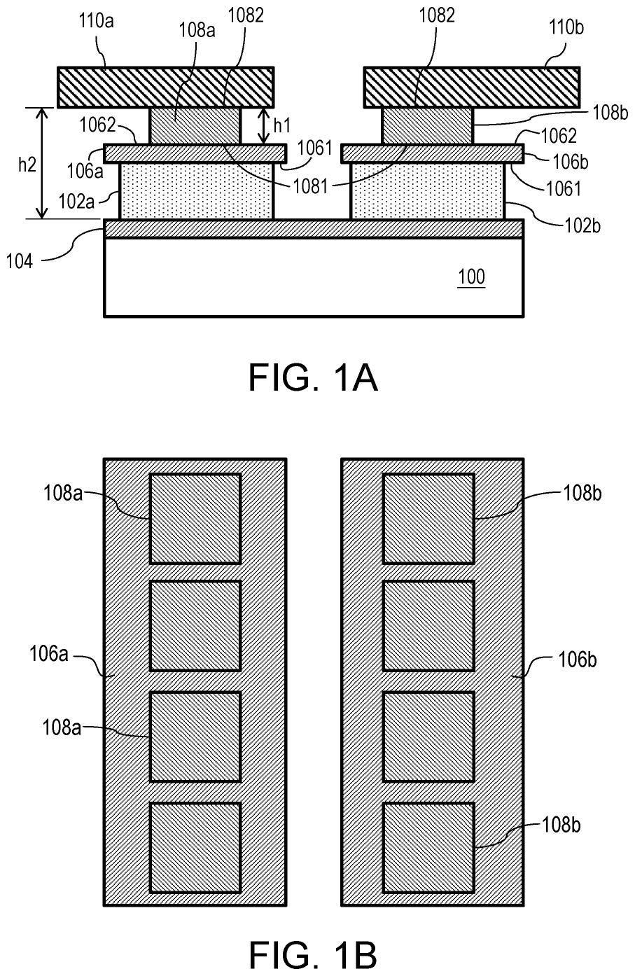

FIG. 1A illustrates a cross-sectional view of a capacitor structure according to some embodiments of the present disclosure. FIG. 1B illustrates a top view of the capacitor structure of FIG. 1A in which some portions are omitted for clarity.

Referring to FIG. 1A, a capacitor structure includes a substrate 100, a plurality of capacitor cells 102a-102b, a first cell plate 104, a plurality of second cell plates 106a-106b, and a plurality of vias 108a-108b. The substrate 100 is, for example, a semiconductor wafer or an insulator substrate. In some embodiments, the substrate 100 is composed of silicon or glass. The capacitor cells 102a-102b are formed upon the substrate 100. In one embodiment, the capacitor cells 102a-102b may be formed in the substrate 100. In another embodiment, the capacitor cells 102a-102b may be formed on the substrate 100. For example, the capacitor cells 102a-102b may be formed in the area of MEOL (meddle-end-of-line) on the substrate 100. The first cell plate 104 is disposed between the substrate 100 and the plurality of capacitor cells 102a-102b. In some embodiments, the first cell plate 104 is configured to be a single plate for connecting the plurality of capacitor cells 102a-102b. The second cell plates 106a-106b are disposed on the capacitor cells 102a-102b, respectively. For example, the second cell plate 106a is disposed on the capacitor cell 102a, and the second cell plate 106b is disposed on the capacitor cell 102b. The vias 108a-108b are disposed on the second cell plates 106a-106b. In some embodiments, the second cell plate 106a comprises a first surface 1061 and a second surface 1062, the first surface 1061 attaches to the capacitor cell 102a, and the second surface 1062 attaches to the via 108a. In some embodiments, the second cell plate 106b comprises a first surface 1061 and a second surface 1062, the first surface 1061 attaches to the capacitor cell 102b, and the second surface 1062 attaches to the via 108b. For example, the via 108a may directly attach the second cell plate 106a, and the via 108b may directly attach the second cell plate 106b. In the disclosure, the larger the second cell plate 106a or 106b is, the more vias 108a or 108b are. Thus, the resistance introduced by the vias 108a or 108b may be reduced. If the area of the second cell plate 106a is larger than that of the second cell plate 106b, the number of the via 108a may be more than that of the via 108b. Moreover, if the areas of the second cell plates 106a-106b are increased, the numbers of the vias 108a-108b thereon may be adjusted (e.g. increased into two or more vias) or kept intact.

FIG. 1B merely shows the vias 108a-108b and the second cell plates 106a-106b for clarity. Referring to FIG. 1B, viewing from the top of the capacitor structure, each of the vias 108a-108b overlaps with each of the second cell plates 106a-106b. The top of the capacitor structure is the topmost portion of the capacitor structure in the top view, e.g. the vias 108a-108b. In some embodiments, the second cell plate 106a has a first surface area, a predetermined number of vias 108a (e.g. four vias 108a or more) are disposed on the second cell plate 106a and occupy a second surface area of the second cell plate 106a, and the second surface area is at least a half of the first surface area. Similarly, the second cell plate 106b has a first surface area, a predetermined number of vias 108b (e.g. four vias 108b or more) are disposed on the second cell plate 106b and occupy a second surface area of the second cell plate 106b, and the second surface area is at least a half of the first surface area. In other words, the vias 108a and vias 108b may be arranged to maximize their coverage on the second cell plate 106a and the second cell plate 106b, respectively, in order to minimize the resistance introduced by the vias 108a and vias 108b.

Referring to FIG. 1A again, the first cell plate 104 is electrically connected to the capacitor cells 102a-102b. In some embodiments, each of the capacitor cells 102a-102b comprises a metal-insulator-metal (MIM) capacitor. In some embodiments, each of capacitor cells 102a-102b comprises a stacked capacitor. In some embodiments, each of capacitor cells 102a-102b comprises a crown type capacitor.

In some embodiments, each of the capacitor cells 102a-102b includes a first conductor film (not shown) connected to the first cell plate 104, a second conductor film (not shown) connected to the second cell plates 106a-106b, and a dielectric layer (not shown) between the first conductor film and the second conductor film. In some embodiments, the capacitor cell 102a-102b may have complicated configuration for improvement of capacitance density.

In FIG. 1A, the capacitor structure further includes a plurality of metal layers 110a-110b over the plurality of second cell plates 106a-106b, and each of the metal layers 110a-110b connects each of the second cell plates 106a-106b through the vias 108a-108b, respectively. For example, the metal layer 110a connects the second cell plate 106a through the via 108a, and the metal layer 110b connects the second cell plate 106b through the via 108b. In some embodiments, the plurality of metal layers 110a-110b are disposed on the plurality of vias 108a-108b, wherein the via 108a comprises a first end 1081 and a second end 1082, the first end 1081 attaches to the second cell plate 106a, and the second end 1082 attaches to the metal layer 110a; the via 108b also comprises a first end 1081 and a second end 1082, the first end 1081 attaches to the second cell plate 106b, and the second end 1082 attaches to the metal layer 110b. In some embodiments, the metal layers 110a-110b are one layer of a BEOL (back-end-of-line) structure, such as the first metal layer (M1), etc. In some embodiments, the metal layers 110a-110b are one layer of a MEOL (meddle-end-of-line) structure which is formed prior to the BEOL structure. In some embodiments, the metal layers 110a-110b are copper or tungsten layers.

In comparison with conventional structure for connecting capacitor cells in series by disposing vias to connect to the bottom cell plates, the vias 108a-108b connected to the second cell plates 106a-106b are shorter than those connected to the bottom cell plates (e.g. the first cell plate 104), and thus resistance of the vias 108a-108b connected to the second cell plate 106a-106b can also be lower than those connected to the bottom cell plates. In addition, a height h1 of the via 108a or 108b connected to the second cell plate 106a or 106b is much shorter than that connected to the bottom cell plates. For example, a height h1 of one of the plurality of vias 108a-108b is less than a half of a height h2 measured from the plurality of metal layers 110a-110b to the first cell plate 104. Accordingly, the capacitor structure of the present disclosure has better ESR (equivalent series resistance), thereby reducing RC (resistance capacitance) to improve operating speed. For example, RC of the capacitor structure may be lower than 250 ps in some embodiments.

Moreover, in comparison with above conventional structure, the electric current loop in the capacitor structure of the present disclosure is less than that in the conventional structure, and thus the capacitor structure of the present disclosure has better ESL (equivalent series inductance).

Furthermore, since the vias 108a-108b are formed on the top plate of the capacitor cells 102a-102b, i.e. overlap with the capacitor cells 102a-102b, it means that the present capacitor structure may have larger capacitance in comparison to the conventional capacitor structure when the present capacitor structure and the conventional capacitor structure have the same bottom plate area. Alternatively, when the present capacitor structure is designed to have the same capacitance with the conventional capacitor structure, the present capacitor structure may have smaller area in comparison to the conventional capacitor structure.

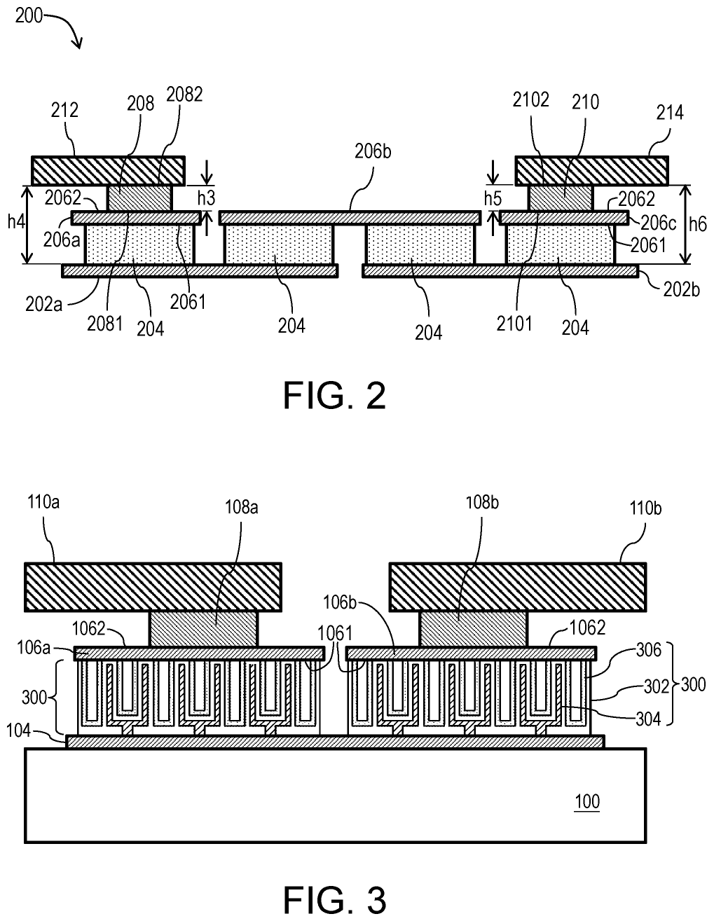

FIG. 2 illustrates a cross-sectional view of a capacitor structure according to some embodiments of the present disclosure.

Referring to FIG. 2, a capacitor structure 200 includes a plurality of bottom cell plates 202a-202b, a plurality of capacitor cells 204, a plurality of top cell plates 206a, 206b and 206c, a first via 208, and a second via 210. The capacitor cells 204 are connected in series between the first via 208 and the second via 206. The capacitor cells 204 are disposed on the bottom cell plates 202a-202b, and the top cell plates 206a, 206b and 206c are disposed on the capacitor cells 204. In some embodiments, a substrate (not shown) is disposed below the capacitor structure 200 to accommodate the same, and in some embodiments, the substrate is composed of silicon or glass. The top cell plate 206a connects to one of the capacitor cells 204, the bottom cell plate 202a connects to two of the capacitor cells 204, the top cell plate 206b connects to two of the capacitor cells 204, the bottom cell plate 202b connects to two of the capacitor cells 204, and the top cell plate 206c connects to one of the capacitor cells 204. Each of the bottom cell plate 202a, the top cell plate 206b, and the bottom cell plate 202b connects two of the capacitor cells 204, and they would not connect the same two of the capacitor cells 204.

As shown in FIG. 2, the first via 208 is disposed on the top cell plate 206a, and the second via 210 is disposed on the top cell plate 206c. In some embodiments, the top cell plate 206a comprises a first surface 2061 and a second surface 2062, the first surface 2061 attaches to one of the capacitor cells 204, and the second surface 2062 attaches to the first via 208. In some embodiments, the top cell plate 206c also comprises a first surface 2061 and a second surface 2062, the first surface 2061 attaches to one of the capacitor cells 204, and the second surface 2062 attaches to the second via 210. The top cell plate 206a connects to the first via 208 is at one end of the capacitor structure 200, and the top cell plate 206c connects to the second via 210 is at the other end of the capacitor structure 200. In some embodiments, viewing from the top of the capacitor structure 200, the first via 208 overlaps with the top cell plate 206a, and the second via 210 overlaps with the top cell plate 206c. In the disclosure, the larger the top cell plate 206a or 206c is, the more the first vias 208 or the second via 210 are. Thus, the resistance introduced by the vias 208 or 210 may be reduced. Moreover, if the area of the top cell plate 206a is larger than that of the top cell plate 206c, the number of the first via 208 may be more than that of the second via 210. Alternatively, if the areas of the top cell plate 206a and the top cell plate 206c are increased, the numbers of the first vias 208 and the second via 210 also have to increase. In some embodiments, the bottom cell plates 202a-202b are electrically connected to the capacitor cells 204. In some embodiments, each of the capacitor cells 204 comprise a metal-insulator-metal (MIM) capacitor. In some embodiments, each of the capacitor cells 204 comprises a stacked capacitor. In some embodiments, each of the capacitor cells 204 comprises a crown type capacitor.

Referring to FIG. 2 again, the capacitor structure 200 further includes a first metal layer 212 disposed over the top cell plate 206a and connecting to the first via 208, and a second metal layer 214 disposed over the top cell plate 206c and connecting to the second via 210. In some embodiments, a height h3 of the first via 208 is less than a half of a height h4 measured from the first metal layer 212 to the bottom cell plate 202a, and a height h5 of the second via 210 is less than a half of a height h6 measured from the second metal layer 214 to the bottom cell plate 202b. In some embodiments, the first metal layer 212 is disposed on the first via 208, the second metal layer 214 is disposed on the second via 210, and the first via 208 comprises a first end 2081 and a second end 2082, wherein the first end 2081 attaches to the top cell plate 206a, and the second end 2082 attaches to the first metal layer 212. The second via 210 comprises a first end 2101 and a second end 2102, wherein the first end 2101 attaches to the top cell plate 206c, and the second end 2102 attaches to the second metal layer 214. In some embodiments, the first metal layer 212 and the second metal layer 214 are one layer of a BEOL structure, such as the first metal layer (M1), etc. In some embodiments, the first metal layer 212 and the second metal layer 214 are one layer of a MEOL structure which is formed prior to the BEOL structure.

FIG. 3 illustrates a cross-sectional view of a capacitor structure according to some embodiments of the present disclose, wherein the reference symbols used in FIG. 1A are used to equally represent the same or similar components.

The difference between the capacitor structure of FIG. 1A and the capacitor structure of FIG. 3 is the construction of the capacitor cells. Referring to FIG. 3, the capacitor cells 300 are disposed between the first cell plate 104 and the second cell plates 106a-106b, and each of the capacitor cells 300 includes a first conductor film 304, a second conductor film 306, and a dielectric layer 302 therebetween. The first conductor film 304 is connected to the first cell plate 304. The second conductor film 306 is connected to a corresponding second cell plate of the second cell plates 106a-106b. The dielectric layer 302 is formed between the first conductor film 304 and the second conductor film 306. In some embodiments, the capacitor cells 300 may have complicated configuration for improvement of capacitance density; for example, the first conductor film 304 has a 3D (three-dimensional) shape of crown, tube, or wavy, and the second conductor film 306 also has a 3D shape of crown, tube, or wavy which is complementary to the first conductor film 304. Furthermore, in a top view, the 3D shapes of the first conductor film 304 and the second conductor film 306 may be arranged to be a rectangular array, a hexagonal array in some embodiments. In some embodiments, the first conductor film 304 and the second conductor film 306 are metal films, and the dielectric layer 302 is composed of high-k dielectric material. For example, the high-k dielectric material may contain at least one of oxides of La (Lanthanum), Ha (Hafnium), and Zr (Zirconium), or another applicable material.

As above, the capacitor structure of the disclosure has better ESR and large capacitance resulting in low RC, and thus it is suitably applied on high power density device for HPC (High-Performance Computing) or AI applications. Accordingly, the capacitor structure may be integrated with WoW (Wafer on Wafer) product or interposer. In addition, since the capacitor structure of the disclosure can have both high capacitance density and reduced area, it can also be adapted to device minimization. Accordingly, the capacitor structure may be integrated with SoC (System-on-Chip) architectures for mobile products or IoT (Internet of Things) applications.

Several examples are listed below to verify effects of the disclosure, but these experiments and their results are not intended to limit a scope of application of the disclosure.

### Experimental Example

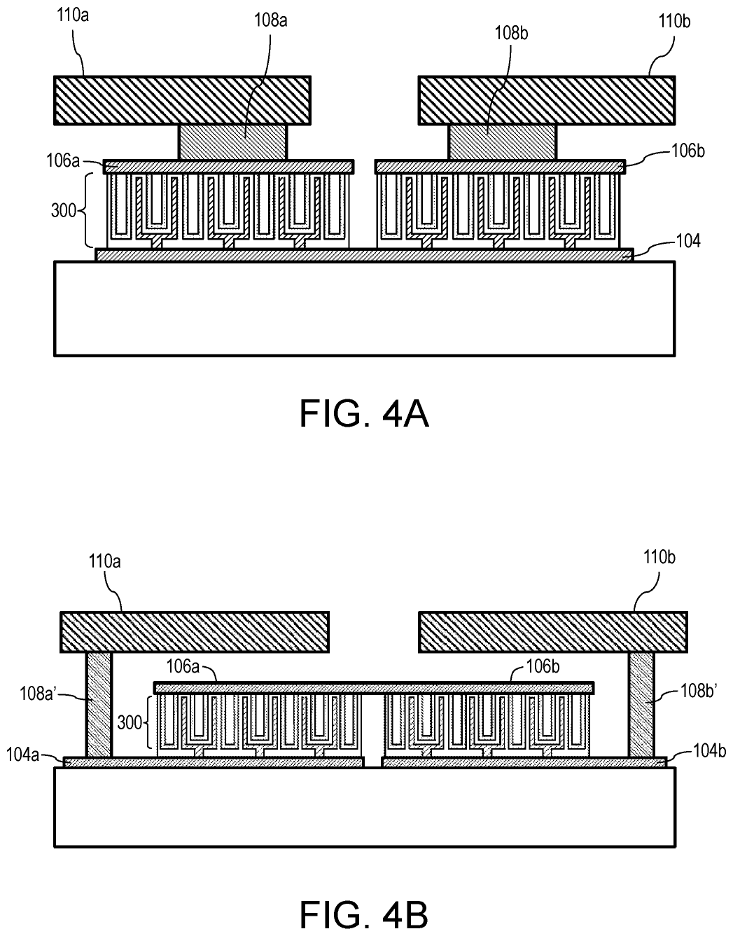

As shown FIG. 4A, the capacitor structure of the experimental example is the same as the capacitor structure of FIG. 3.

### Comparative Example

FIG. 4B is a schematic cross-sectional view of a capacitor structure of a comparative example. In FIG. 4B, the capacitor cells 300 are the same as those in FIG. 4A, but second cell plates 106a-106b are connected into one layer, and bottom cell plates 104a and 104b are separated from each other. Accordingly, the metal layer 110a is connected to the bottom cell plate 104a through a vias 108a′, and the metal layer 110b is connected to the bottom cell plate 104b through a vias 108b′.

[Dynamic IR Performance (PDN with IPC)]

For Dynamic IR simulation, it is assumed that the operation voltage is 1.2V, and the admissible voltage variation is ±5% (i.e. 1.14V-1.26V).

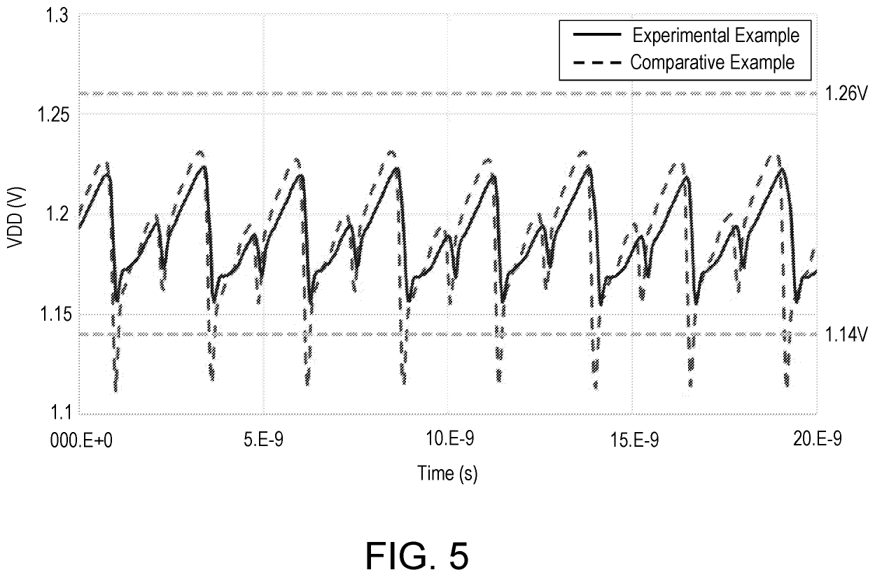

FIG. 5 is a voltage curve graph along times of the experimental example and the comparative example, measured using Dynamic IR simulation.

Referring to FIG. 5, the voltage variation of the experimental example is within the range of 1.14V-1.26V, but the voltage variation of the comparative example is obviously out of the range. The numerical values in FIG. 5 are further described in Table 1 below.

TABLE 1

| | Comparative | Experimental |
|---|---|---|
| | example | example |
| Status | Fail | Pass |
| Vₘₐₓ | 1.231 | 1.224 |
| Vₘᵢₙ | 1.112 | 1.154 |
| Vₚ₋ₚ (mV) | 122.5 | 70.4 |
| Vₚ₋ₚ ratio | 1x | 0.57x |

Vₚ₋ₚ may be obtained from the difference between Vₘₐₓ and Vₘᵢₙ in mV.
Vₚ₋ₚ ratio may be calculated by 1-(122.5-70.4)/122.5.

It may be seen from Table 1 that the voltage variation of the experimental example can be reduced to 0.57 times than that of the comparative example.

### [IPC Impedance Curve]

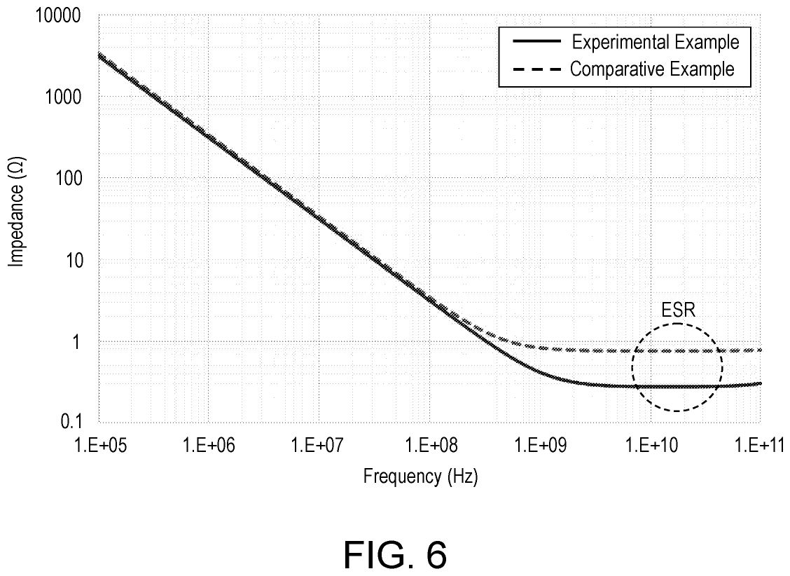

FIG. 6 shows simulated impedance curves of the experimental example and the comparative example. As shown in FIG. 6, the impedance of the experimental example is much lower than that of the comparative example at high frequency. Therefore, the experimental example has better ESR (equivalent series resistance).

Table 2 below lists the simulated values from IPC Impedance Curve.

| | Comparative | Experimental | |
|---|---|---|---|
| | example | example | Improvement |
| C (nF) | 0.476 | 0.514 | 8% |
| ESR (mΩ) | 857.5 | 273.0 | 68% |
| ESL (pH) | 0.291 | 0.208 | 29% |
| RC (ps) | 408.2 | 140.3 | 66% |

The improvement is obtained from a percentage of a difference value between the experimental example and the comparative example to the value of Comparative example.

It may be seen from Table 2 that the experimental example has improved results in ESR, ESL (equivalent series inductance), and RC (resistance-capacitance).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A capacitor structure, comprising:
a substrate;
a plurality of capacitor cells formed upon the substrate;
a first cell plate disposed between the substrate and the plurality of capacitor cells;
a plurality of second cell plates disposed on the plurality of capacitor cells respectively; and
a plurality of vias disposed on the plurality of second cell plates.

2. The capacitor structure of claim 1, wherein, for one of the second cell plates, the second cell plate comprises a first surface and a second surface, the first surface attaches to one of the plurality of capacitor cells, and the second surface attaches to one of the plurality of vias.

3. The capacitor structure of claim 1, further comprising:
a plurality of metal layers disposed on the plurality of vias;
wherein, for one of the plurality of vias, the via comprises a first end and a second end, the first end attaches to one of the plurality of second cell plates, and the second end attaches to one of the plurality of metal layers.

4. The capacitor structure of claim 1, wherein the plurality of vias overlaps with the plurality of second cell plates viewing from the top of the capacitor structure.

5. The capacitor structure of claim 1, wherein, for one of the second cell plates, the second cell plate has a first surface area, a predetermined number of vias are disposed on the second cell plate and occupy a second surface area of the second cell plate, and the second surface area is at least a half of the first surface area.

6. The capacitor structure of claim 1, wherein the first cell plate configured to be a single plate for connecting the plurality of capacitor cells.

7. The capacitor structure of claim 1, wherein each of the plurality of capacitor cells comprises a metal-insulator-metal (MIM) capacitor, a stacked capacitor, or a crown type capacitor.

8. The capacitor structure of claim 1, wherein each of the capacitor cells comprises:
a first conductor film connected to the first cell plate;
a second conductor film connected to a corresponding second cell plate of the plurality of second cell plates; and
a dielectric layer formed between the first conductor film and the second conductor film.

9. The capacitor structure of claim 1, further comprising a plurality of metal layers over the plurality of second cell plates and connecting to the plurality of second cell plates through the plurality of vias respectively.

10. The capacitor structure of claim 9, wherein a height of one of the plurality of vias is less than a half of a height measured from the plurality of metal layers to the first cell plate.

11. A capacitor structure, comprising:
at least one bottom cell plate;
a plurality of capacitor cells disposed on the at least one bottom cell plate;
a plurality of top cell plates disposed on the plurality of capacitor cells;
a first via disposed on one of the plurality of top cell plates; and
a second via disposed on another one of the plurality of top cell plates, wherein
the plurality of capacitor cells is connected in series between the first via and the second via.

12. The capacitor structure of claim 11, wherein, for one of the top cell plates, the top cell plate comprises a first surface and a second surface, the first surface attaches to one of the plurality of capacitor cells, and the second surface attaches to one of the first via and the second via.

13. The capacitor structure of claim 11, wherein the one of the plurality of top cell plates connected to the first via is at one end of the capacitor structure, and the another one of the plurality of top cell plates connected to the second via is at the other end of the capacitor structure.

14. The capacitor structure of claim 13, wherein the first via overlaps with the one of the plurality of top cell plates viewing from the top of the capacitor structure.

15. The capacitor structure of claim 13, wherein the second via overlaps with the another one of the plurality of top cell plates viewing from the top of the capacitor structure.

16. The capacitor structure of claim 11, wherein the at least one bottom cell plate is electrically connected to the plurality of capacitor cells.

17. The capacitor structure of claim 11, wherein each of the plurality of capacitor cells comprise a metal-insulator-metal (MIM) capacitor, a stacked capacitor, or a crown type capacitor.

18. The capacitor structure of claim 11, further comprising:
a first metal layer disposed over the plurality of top cell plates and connecting to the first via; and
a second metal layer disposed over the plurality of top cell plates and connecting to the second via.

19. The capacitor structure of claim 18, wherein a height of the first via is less than a half of a height measured from the first metal layer to the at least one bottom cell plate.

20. The capacitor structure of claim 18, wherein a height of the second via is less than a half of a height measured from the second metal layer to the at least one bottom cell plate.
